(19) United States
(12) Patent Application Publication
(10) Pub. No.: US 2013/0181218 A1
(43) Pub. Date: Jul. 18, 2013

(54) WIRING STRUCTURE AND DISPLAY DEVICE

(71) Applicants: Takeaki Maeda, Kobe-shi (JP); Toshihiro Kugimiya, Kobe-shi (JP)

(72) Inventors: Takeaki Maeda, Kobe-shi (JP); Toshihiro Kugimiya, Kobe-shi (JP)

(73) Assignee: KABUSHIKI KAISHA KOBE SEIKO SHO (KOBE STEEL, LTD.), Kobe-shi (JP)

(21) Appl. No.: 13/877,065

(22) PCT Filed: Sep. 30, 2011
(86) PCT No.: PCT/JP11/72590

§ 371 Date: Mar. 29, 2013

(30) Foreign Application Priority Data
Sep. 30, 2010 (JP) 2010-222002
Sep. 29, 2011 (JP) 2011-215071

(51) Int. Cl. H01L 23/532

(52) U.S. Cl. CPC H01L 23/53238
USPC 257/43

(57) ABSTRACT

An interconnection structure includes a semiconductor layer of a thin-film transistor and a metal interconnection film above a substrate in this order from a side of the substrate, and includes a barrier layer between the semiconductor layer and the metal interconnection film. The semiconductor layer is composed of an oxide semiconductor. The barrier layer is composed of a Ti oxide film containing TiOx (where x is from 1.0 to 2.0), and the Ti oxide film is directly connected to the semiconductor layer. The oxide semiconductor is composed of an oxide containing at least one element selected from the group consisting of In, Ga, Zn and Sn.

### TECHNICAL FIELD

The present invention relates to a technique useful for interconnection structures which includes an oxide semiconductor layer as the semiconductor layer therein and is for use in flat panel displays in liquid-crystal display devices, organic EL display devices or the like.

### BACKGROUND ART

As the interconnection material for display devices represented by liquid-crystal display devices or the like, an aluminium (Al) alloy film excellent in workability and having a relatively low electrical resistance is generally used. Recently, as the interconnection material for display devices applicable to large-sized and high-definition display devices, attention is paid to copper (Cu) having a lower resistance than Al. The electrical resistivity of Al is 2.5×10⁻⁶ Ω·cm while the electrical resistivity of Cu is 1.6×10⁻⁶ Ω·cm and is low.

On the other hand, as the semiconductor layer for use in display devices, attention is paid to oxide semiconductors. Oxide semiconductors have a higher carrier mobility as compared with all-purpose amorphous silicon (a-Si), have a large optical band gap, can be deposited at a low temperature, and are therefore expected to be applicable to next-generation displays that are required to be large-sized, to have high resolution and to be operable at high speed, and also to resin substrates having low heat resistance.

An oxide semiconductor contains at least one element selected from the group consisting of In, Ga, Zn and Sn, and for example, In-containing oxide semiconductors (In—Ga—Zn—O, In—Zn—Sn—O, In—Zn—O and the like) are typically mentioned. In addition, as oxide semiconductors of which the material cost can be reduced because of not containing In which is a rare metal and which are suitable to massive production, Zn-containing oxide semiconductors (Zn—Sn—O, Ga—Zn—Sn—O and the like) has been also proposed (for example, Patent Document 1).

### PRIOR ART DOCUMENT

### Patent Document

Patent Document 1: JP-A-2004-163901

### SUMMARY OF THE INVENTION

### Problems to be Solved by the Invention

However, when an oxide semiconductor is used as the semiconductor layer in, for example, bottom gate type TFT and a Cu film is used as the interconnection material for the source electrode or the drain electrode to be directly connected to the oxide semiconductor, then there occurs a problem that Cu diffuses into the oxide semiconductor layer and the TFT properties are thereby worsened. Consequently, a barrier metal capable of preventing the diffusion of Cu into the oxide semiconductor is needed between the oxide semiconductor and the Cu film; however, when Ti or the like which is generally used as a barrier metal is employed, then it undergoes oxidation-reduction reaction with the underlying oxide semiconductor after heat treatment, which causes compositional change in the oxide semiconductor and involves a negative effect on the TFT properties, and further causes a problem that the Cu film is peeled away.

Not limited to Cu, the foregoing problem is also seen in other cases where an Al film is used as the interconnection material.

The present invention has been made in consideration of such a situation, and an object thereof is to provide an interconnection structure capable of forming a stable interface between the oxide semiconductor layer and the metal film constituting, for example, a source electrode or a drain electrode in display devices such as organic EL displays or liquid-crystal displays, and to provide the foregoing display devices including the interconnection structure.

### Means for Solving the Problems

The present invention provides the following interconnection structure and display device.

(1) An interconnection structure, including a semiconductor layer of a thin-film transistor and a metal interconnection film above a substrate in this order from a side of the substrate, and including a barrier layer between the semiconductor layer and the metal interconnection film, wherein

the semiconductor layer is composed of an oxide semiconductor,

the barrier layer is composed of a Ti oxide film containing TiOx (where x is from 1.0 to 2.0), and the Ti oxide film is directly connected to the semiconductor layer, and

the oxide semiconductor is composed of an oxide containing at least one element selected from the group consisting of In, Ga, Zn and Sn.

(2) The interconnection structure according to (1), wherein

the metal interconnection film has a single-layer structure or a laminated structure,

when the metal interconnection film has the single-layer structure, the metal interconnection film is composed of a pure Al film, an Al alloy film containing 90 atomic % or more of Al, a pure Cu film, or a Cu alloy film containing 90 atomic % or more of Cu, and

when the metal interconnection film has the laminated structure, the metal interconnection film is composed of, in this order from the side of the substrate: a pure Ti film or a Ti alloy film containing 50 atomic % or more of Ti, and a pure Al film or an Al alloy film containing 90 atomic % or more of Al; or a pure Ti film or a Ti alloy film containing 50 atomic % or more of Ti, and a pure Cu film or a Cu alloy film containing 90 atomic % or more of Cu.

(3) A display device, including the interconnection structure according to (1).

(4) A display device, including the interconnection structure according to (2).

### Advantage of the Invention

According to the present invention, in the interconnection structure including an oxide semiconductor layer, a Ti oxide is used in place of Ti metal as the barrier layer for effectively preventing the metal constituting the interconnection material from diffusing into the oxide semiconductor; and therefore, stable TFT properties can be obtained, and a display device having a further enhanced quality can be provided.

### BRIEF DESCRIPTION OF THE DRAWING

FIG. 1 is a cross-sectional view schematically showing the configuration of the interconnection structure of the present invention.

### EMBODIMENTS FOR CARRYING OUT THE INVENTION

The present inventors have made various investigations for forming a stable interface between a metal interconnection film for electrodes such as a source electrode and a drain electrode, and an oxide semiconductor layer (the oxide semiconductor layer is disposed below and the metal interconnection film is disposed above, as seen from the side of the substrate). As a result, the present inventors have found that, when an Ti oxide film is interposed between the underlying oxide semiconductor layer and the metal interconnection film, then the oxidation reduction reaction with the oxide semiconductor can be prevented, and the metal constituting the metal interconnection film can be prevented from diffusing into the oxide semiconductor, and also the elements constituting the oxide semiconductor can be prevented from diffusing into the metal interconnection film, and consequently the intended object can be attained; and the present inventors have completed the present invention.

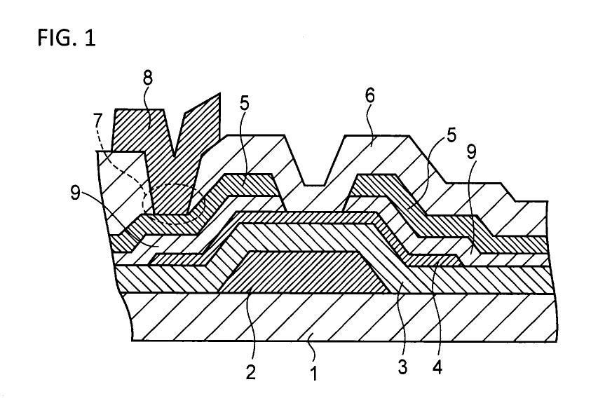

With reference to FIG. 1, an embodiment of the interconnection structure of the present invention is described below. FIG. 1 and the production method of the interconnection structure to be mentioned below show one example of a preferred embodiment of the present invention, and the present invention is not intended to be restricted thereto. For example, FIG. 1 shows a bottom gate type structured TFT, to which the present invention is not limited, but a top gate type TFT where the gate insulating film and the gate electrode are disposed in this order above the oxide semiconductor layer may be used.

As shown in FIG. 1, the interconnection structure of the present invention is so configured that a gate electrode 2 and a gate insulating film 3 are formed on/above a substrate 1, and an oxide semiconductor layer 4 is formed thereon. Above the oxide semiconductor layer 4, a source electrode/drain electrode 5 are formed, and a protective film (insulating film) 6 is formed thereon; and via a contact hole 7, a transparent conductive film 8 is electrically connected to the drain electrode 5.

The characteristic feature of the interconnection structure of the present invention is that the structure has a Ti oxide film 9 in place of conventional Ti or the like, between the source/drain electrode 5 and the oxide semiconductor layer 4. As shown in FIG. 1, the Ti oxide film 9 is directly connected to the oxide semiconductor layer 4. The Ti oxide film 9 inhibits the reduction reaction with the underlying oxide semiconductor layer owing to the heat hysteresis (protective layer formation or the like) after the source/drain electrode formation, and has an effect as a barrier layer (effect capable of preventing metal diffusion into the semiconductor layer and semiconductor diffusion into the source/drain electrode).

The Ti oxide film 9 contains a Ti oxide. The composition of the Ti oxide for use in the present invention may be represented by TiOx, where x is preferably from 1.0 to 2.0. More preferably, x is 1.5, and is even more preferably 2.0. The Ti oxide may be composed of Ti and O alone, but may further include any metal (e.g., Al, Mn, Zn) other than Ti within a range not detracting from the advantage of the present invention.

For sufficiently exhibiting the barrier effect, it is preferred that the thickness of the Ti oxide film 9 is approximately 10 nm or more, more preferably 20 nm or more, even more preferably 30 nm or more. On the other hand, when the film is too thick, the microworkability thereof worsens, and therefore, the upper limit of the thickness is preferably 50 nm, more preferably 40 nm.

The interconnection structure of the present invention is characterized in that the Ti oxide film 9 is interposed as a barrier layer, and the other requirements to constitute the interconnection structure are not specifically defined but may be suitably selected from any ones generally used in ordinary interconnection structures. For example, as the metal constituting the source/drain electrode 5, a pure Al film or an Al alloy film containing 90 atomic % or more of Al, or a pure Cu film or a Cu alloy film containing 90 atomic % or more of Cu is preferably used, in consideration of the viewpoint of electrical resistance or the like. These may have a single-layered structure or a laminated structure (in that order from the side of the substrate: (i) a laminated structure of a pure Ti film or a Ti alloy film containing 50 atomic % or more of Ti, and a pure Al film or an Al alloy film; or (ii) a laminated structure of a pure Ti film or a Ti alloy film containing 50 atomic % or more of Ti, and a pure Cu film or a Cu alloy film).

Here “pure Al” means Al which does not contain any third element intentionally added for characteristic improvement, and contains only an unavoidable impurity. “Al alloy” contains approximately 90 atomic % or more of Al with a remainder being an alloying element except Al and an unavoidable impurity. Here as the “alloying element except Al”, an alloying element having a low electrical resistance is exemplified, and specific examples thereof include Si, Cu, Nd, La, and the like. In the Al alloy containing such an alloying element, it is preferred that the electrical resistivity is so controlled as to be 5.0×10⁻⁶ Ω·cm or less by controlling the amount thereof to be added, the film thickness or the like.

“Pure Cu” means Cu which does not contain any third element intentionally added for characteristic improvement, and contains only an unavoidable impurity. “Cu alloy” contains approximately 90 atomic % or more of Cu with a remainder being an alloying element except Cu and an unavoidable impurity. Here as the “alloying element except Cu”, an alloying element having a low electrical resistance is exemplified, and specific examples thereof include Mn, Ni, Ge, Mg, Ca, and the like.

In the Cu alloy containing such an alloying element, it is preferred that the electrical resistivity is so controlled as to be 4.0×10⁻⁶ Ω·cm or less by controlling the amount thereof to be added, the film thickness or the like.

“Pure Ti” means Ti which does not contain any third element intentionally added for characteristic improvement, and contains only an unavoidable impurity. “Ti alloy” contains approximately 50 atomic % or more of Ti with a remainder being an alloying element except Ti and an unavoidable impurity. Here as the “alloying element except Ti”, an alloying element which does not have any negative influence on microworkability is exemplified, and specific examples thereof include Al, Mn, Zn, and the like.

It is preferred that the oxide constituting the oxide semiconductor layer 4 is an oxide containing at least one element selected from the group consisting of In, Ga, Zn and Sn. Specific examples thereof include an In-containing oxide semiconductor (In—Ga—Zn—O, In—Zn—Sn—O, In—Zn—O and the like), a Zn-containing oxide semiconductor which does not include In (ZnO, Zn—Sn—O, Ga—Zn—Sn—O, Al—Ga—Zn—O and the like), and the like. The compositional ratio of these is not particularly limited and may fall within an ordinary range.

The substrate 1 is not particularly limited as long as it is a substrate generally used in ordinary display devices, and examples thereof include transparent substrates such as alkali-free glass substrates, high-strain-point glass substrates and soda lime glass substrates, as well as Si substrates, thin metal plates of stainless or the like, resin substrates such as PET films, and the like.

The metal material for use as the gate electrode 2 is not also particularly limited as long as it is a metal material generally used in ordinary display devices, and examples thereof include metals having a low electrical resistivity such as Al and Cu and their alloys. Concretely, the metal material used for the foregoing source/drain electrode 5 (pure Al or Al alloy, pure Cu or Cu alloy) is preferably used. The gate electrode 2 and the source/drain electrode 5 may be composed of the same metal material.

The gate insulating film 3 and the protective film (insulating film) 6 are not also particularly limited as long as they are a gate insulating film and a protective film, which are generally used in ordinary display devices, and typical examples thereof include silicon oxide films, silicon nitride films, silicon oxynitride films and the like. In addition, oxides such as Al₂O₃ and Y₂O₃, and those prepared by laminating these may also be used.

The material for use for the transparent conductive film 8 is not also particularly limited as long as it is a material generally used in ordinary display devices, and examples thereof include oxide conductors such as ITO, IZO and ZnO.

Next, a method for producing the foregoing interconnection material in a preferred embodiment is described below, which, however, is not intended to restrict the present invention thereto.

First, the gate electrode 2 and the gate insulating film 3 are formed on/above the substrate 1. The method is not specifically defined, and any ordinary method generally employed for display devices may be used. For example, a CVD (chemical vapor deposition) process or the like is exemplified.

Next, the oxide semiconductor layer 4 is formed. It is preferred that the oxide semiconductor layer 4 is deposited according to a DC sputtering process or an RF sputtering process that uses a sputtering target having the same composition as that of the semiconductor layer 4.

Next, the oxide semiconductor layer 4 is wet-etched, followed by patterning. Immediately after the patterning, it is desirable that the oxide semiconductor layer 4 is heat-treated (pre-annealed) for improving the film quality thereof, and according to this, the transistor properties thereof, or that is, the on-current and the field effect mobility increase and the transistor performance is thereby enhanced. As the pre-annealing condition, for example, there may be mentioned heat treatment in an air or oxygen atmosphere at about 250 to 400° C. for about 1 to 2 hours.

After the pre-annealing, the Ti oxide film 9 that is the characteristic part of the present invention, and the source/drain electrode 5 are formed. Concretely, for example, according to a magnetron sputtering process, the Ti oxide film 9, and a metal film constituting the source/drain electrode 5 (for example, laminate of pure Ti film and pure Cu film) are deposited, and then, according to a lift-off process, the source/drain electrode 5 may be formed. Apart from the foregoing lift-off process to form the source/drain electrode 5, there may be mentioned a different method in which a predetermined Ti oxide film, a pure Ti film and a pure Cu film are previously formed in this order according to a sputtering process and thereafter the source/drain electrode 5 is formed through patterning. In this method, however, the oxide semiconductor layer 4 is damaged when the source/drain electrode 5 is etched, and therefore the transistor properties are thereby worsened. Consequently, for evading the problem, employed examples thereof may include a process where a protective film such as SiO₂ is previously formed on the oxide semiconductor layer 4 according to a CVD process or the like, and thereafter the source/drain electrode 5 is formed, followed by patterning.

Next, the protective film (insulating film) 6 is formed on the oxide semiconductor layer 4, for example, according to a CVD process. The surface of the oxide semiconductor film 4 is readily in a conduction state owing to the plasma damage by CVD (probably it is presumed that the oxygen defects formed on the surface of the oxide semiconductor would be electron donors), and therefore it is desirable that N₂O plasma irradiation is carried out before deposition of the protective film 6. Regarding the N₂O plasma irradiation condition, the condition described in the following reference: J. Park et al., Appl. Phys. Lett., 1993 053505 (2008) is preferably employed.

Next, on the basis of an ordinary method, the transparent conductive film 8 is electrically connected to the drain electrode 5 via the contact hole 7 to give the interconnection structure of the present invention.

### EXAMPLES

The present invention is more specifically described below with reverence to Examples, but it should not be construed that the present invention is limited to the following Examples. The present invention can also be practiced by applying modifications within a range adaptable to the purports described above and described below, and all of them are encompassed in the technical field of the present invention.

### Example 1

In this Example, the sample prepared according to the following method was used, and the adhesion between the oxide semiconductor and the Ti oxide film, and the diffusion of the oxide semiconductor constituent elements into the metal interconnection film were measured.

### (Preparation of Sample for Adhesion Test)

First, a gate insulating film SiO₂ (200 nm) was deposited on a glass substrate (EAGLE XG, manufactured by Corning Inc., diameter 100 mm×thickness 0.7 mm). The gate insulating film was deposited according to a plasma CVD process, using a mixed gas of SiH₄ and N₂O as the carrier gas, a deposition powder of 100 W and a deposition temperature of 300° C.

Next, on the gate insulating film, various types of oxide semiconductor layers shown in Table 1 to Table 8 were individually deposited according to a sputtering process using a sputtering target. The sputtering condition is as mentioned below. The target composition was so adjusted as to give the desired semiconductor layer.

Target: In—Ga—Zn—O (IGZO)
Zn—Sn—O (ZTO)
Ga—Zn—Sn—O (GZTO)
In—Zn—Sn—O (IZTO)

Substrate temperature: room temperature

Gas pressure: 5 mTorr

Oxygen partial pressure: O₂/(Ar+O₂)=4%

Thickness: 50 nm

Next, for improving the film quality, pre-annealing treatment was carried out. The pre-annealing was carried out under atmospheric pressure at 350° C. for 1 hour.

Next, on the foregoing oxide semiconductor film, a Ti oxide film (TiOx, thickness: 30 nm), a pure Ti film (thickness: 20 nm) and a pure Cu metal interconnection film (thickness 250 nm) each having various types of composition and film thickness shown in Table 1 to Table 8 were deposited, according to a DC magnetron sputtering process. In this Example, a laminate film of pure Ti and pure Cu was used as the metal interconnection film. Precisely, a Ti oxide film was deposited according to a DC reactive sputtering process, and subsequently pure Ti was deposited according to a DC sputtering process, and finally a pure Cu film was deposited according to a DC sputtering process.

Here, the DC reactive sputtering condition for the Ti oxide film is as mentioned below.

Substrate temperature: room temperature

Atmosphere: Ar+O₂

Gas pressure: 2 mTorr

The DC sputtering condition for the pure Ti film and the pure Cu film is as mentioned below.

Target: pure Ti target (for pure Ti film)
pure Cu target (for pure Cu film)

Deposition temperature: room temperature

Carrier gas: Ar

Gas pressure: 2 mTorr

The compositional ratio of the foregoing Ti oxide film (TiOx) was determined through XPS (X-ray photoelectron spectroscopy). Precisely, the ratio was determined on the basis of the peak position of Ti2p of the Ti oxide film in the XPS spectrum and the areal ratio of Ti2p to O1s therein.

### (Adhesion Test to Oxide Semiconductor)

Each sample obtained in the above manner was heat-treated at 350° C. for 30 minutes, and the adhesion of each sample after the heat treatment to an oxide semiconductor (precisely, the adhesion of TiOx to oxide semiconductor) was evaluated in a peeling test with a tape, based on the tape peeling test in accordance with the JIS standard.

Precisely, cross-cuts (cross cuts of 5×5) were provided at intervals of 1 mm on the surface (the side of the pure Cu film) of each sample by using a cutter knife. Subsequently, a black polyester tape, manufactured by ULTRATAPE (product name: ULTRA TAPE #6570) was firmly stuck onto the foregoing surface; the tape was peeled off at once while keeping the peeling angle of the tape at 60°; the number of the divisions of those cross-cuts which had not been peeled off by the tape was counted; and the ratio to all of the divisions (film retention ratio) was determined. The measurement was performed three times, and the average value of those in the measurement of three times was defined as the film retention ratio of each sample.

In this Example, the case where the film retention ratio calculated in the above manner was 90% or more was evaluated as “0”; and the case where the film retention ratio was less than 90% was evaluated as “x”; and “0” (the adhesion to the oxide semiconductor layer was good) was accepted.

(Presence or Absence of Diffusion of Oxide Semiconductor Layer Constituent Elements into Cu Film)

Each sample mentioned above was confirmed through SIMS (secondary ion mass spectrometry) method as to the presence or absence of diffusion of the oxide semiconductor layer constituent elements into the Cu film. The experiment condition was a primary ion condition O₂⁺ under 1 keV. For the evaluation standard for diffusion, the structure of a Cu/Mo/oxide semiconductor layer which did not cause diffusion of the oxide semiconductor layer constituent elements (In, Ga, Zn, Sn) into the Cu film was used as a reference. Relative to the peak intensity of the oxide semiconductor layer constituent elements (In, Ga, Zn, Sn) in the Cu film in the reference structure, those having an intensity of at least 5 times larger than that peak intensity were evaluated to have diffusion of the oxide semiconductor layer constituent elements (failure); while those having an intensity of less than 5 times were evaluated to have no diffusion (good).

These results are summarized and shown in Table 1 to Table 8.

TABLE 1

| | Compositional | | | Ti oxide | | | |
|---|---|---|---|---|---|---|---|
| | ratio | | | film (TiOx) | Properties | | |
| | of IGZO | | | Oxygen | | | Total |
| No. | In | Ga | Zn | ratio (x) | Diffusion | Adhesion | evaluation |
| 1 | 1 | 1 | 1 | — | x | x | x |
| 2 | 1 | 1 | 1 | 0.5 | x | x | x |
| 3 | 1 | 1 | 1 | 1.0 | ∘ | ∘ | ∘ |
| 4 | 1 | 1 | 1 | 2.0 | ∘ | ∘ | ∘ |
| 5 | 2 | 2 | 1 | — | x | x | x |
| 6 | 2 | 2 | 1 | 0.5 | x | x | x |
| 7 | 2 | 2 | 1 | 1.0 | ∘ | ∘ | ∘ |
| 8 | 2 | 2 | 1 | 2.0 | ∘ | ∘ | ∘ |

TABLE 2

| | | | Ti oxide | | | |
|---|---|---|---|---|---|---|
| | Compositional ratio | | film (TiOx) | | | |
| | (atomic ratio) of ZTO | | Oxygen | Properties | | |
| No. | Zn/(Zn + Sn) | Sn/(Zn + Sn) | ratio (x) | Diffusion | Adhesion | Total evaluation |
| 1 | 0.5 | 0.5 | — | x | x | x |
| 2 | 0.5 | 0.5 | 0.5 | x | x | x |
| 3 | 0.5 | 0.5 | 1.0 | ∘ | ∘ | ∘ |
| 4 | 0.5 | 0.5 | 2.0 | ∘ | ∘ | ∘ |
| 5 | 0.67 | 0.33 | — | x | x | x |
| 6 | 0.67 | 0.33 | 0.5 | x | x | x |
| 7 | 0.67 | 0.33 | 1.0 | ∘ | ∘ | ∘ |
| 8 | 0.67 | 0.33 | 2.0 | ∘ | ∘ | ∘ |
| 9 | 0.75 | 0.25 | — | x | x | x |
| 10 | 0.75 | 0.25 | 0.5 | x | x | x |
| 11 | 0.75 | 0.25 | 1.0 | ∘ | ∘ | ∘ |
| 12 | 0.75 | 0.25 | 2.0 | ∘ | ∘ | ∘ |

TABLE 3

| | Compositional ratio (atomic ratio) | | | | | | |
|---|---|---|---|---|---|---|---|
| | of oxide semiconductor | | | Ti oxide film (TiOx) | Properties | | |
| No. | Ga/(Zn + Sn + Ga) | Zn/(Zn + Sn) | Sn/(Zn + Sn) | Oxygen ratio (x) | Diffusion | Adhesion | Total evaluation |
| 1 | 0.05 | 0.5 | 0.5 | — | x | x | x |
| 2 | 0.05 | 0.5 | 0.5 | 0.5 | x | x | x |
| 3 | 0.05 | 0.5 | 0.5 | 1.0 | ∘ | ∘ | ∘ |
| 4 | 0.05 | 0.5 | 0.5 | 2.0 | ∘ | ∘ | ∘ |
| 5 | 0.05 | 0.67 | 0.33 | — | x | x | x |
| 6 | 0.05 | 0.67 | 0.33 | 0.5 | x | x | x |
| 7 | 0.05 | 0.67 | 0.33 | 1.0 | ∘ | ∘ | ∘ |
| 8 | 0.05 | 0.67 | 0.33 | 2.0 | ∘ | ∘ | ∘ |
| 9 | 0.05 | 0.75 | 0.25 | — | x | x | x |
| 10 | 0.05 | 0.75 | 0.25 | 0.5 | x | x | x |
| 11 | 0.05 | 0.75 | 0.25 | 1.0 | ∘ | ∘ | ∘ |
| 12 | 0.05 | 0.75 | 0.25 | 2.0 | ∘ | ∘ | ∘ |
| 13 | 0.1 | 0.5 | 0.5 | — | x | x | x |
| 14 | 0.1 | 0.5 | 0.5 | 0.5 | x | x | x |
| 15 | 0.1 | 0.5 | 0.5 | 1.0 | ∘ | ∘ | ∘ |
| 16 | 0.1 | 0.5 | 0.5 | 2.0 | ∘ | ∘ | ∘ |

TABLE 4

| | Compositional ratio (atomic ratio) | | | | | | |
|---|---|---|---|---|---|---|---|
| | of oxide semiconductor | | | Ti oxide film (TiOx) | Properties | | |
| No. | Ga/(Zn + Sn + Ga) | Zn/(Zn + Sn) | Sn/(Zn + Sn) | Oxygen ratio (x) | Diffusion | Adhesion | Total evaluation |
| 17 | 0.1 | 0.67 | 0.33 | — | x | x | x |
| 18 | 0.1 | 0.67 | 0.33 | 0.5 | x | x | x |
| 19 | 0.1 | 0.67 | 0.33 | 1.0 | ∘ | ∘ | ∘ |
| 20 | 0.1 | 0.67 | 0.33 | 2.0 | ∘ | ∘ | ∘ |
| 21 | 0.1 | 0.75 | 0.25 | — | x | x | x |
| 22 | 0.1 | 0.75 | 0.25 | 0.5 | x | x | x |
| 23 | 0.1 | 0.75 | 0.25 | 1.0 | ∘ | ∘ | ∘ |
| 24 | 0.1 | 0.75 | 0.25 | 2.0 | ∘ | ∘ | ∘ |
| 25 | 0.2 | 0.5 | 0.5 | — | x | x | x |
| 26 | 0.2 | 0.5 | 0.5 | 0.5 | x | x | x |
| 27 | 0.2 | 0.5 | 0.5 | 1.0 | ∘ | ∘ | ∘ |
| 28 | 0.2 | 0.5 | 0.5 | 2.0 | ∘ | ∘ | ∘ |
| 29 | 0.2 | 0.67 | 0.33 | — | x | x | x |
| 30 | 0.2 | 0.67 | 0.33 | 0.5 | x | x | x |
| 31 | 0.2 | 0.67 | 0.33 | 1.0 | ∘ | ∘ | ∘ |
| 32 | 0.2 | 0.67 | 0.33 | 2.0 | ∘ | ∘ | ∘ |

TABLE 5

| | Compositional ratio (atomic ratio) | | | | | | |
|---|---|---|---|---|---|---|---|
| | of oxide semiconductor | | | Ti oxide film (TiOx) | Properties | | |
| No. | Ga/(Zn + Sn + Ga) | Zn/(Zn + Sn) | Sn/(Zn + Sn) | Oxygen ratio (x) | Diffusion | Adhesion | Total evaluation |
| 33 | 0.2 | 0.75 | 0.25 | — | x | x | x |
| 34 | 0.2 | 0.75 | 0.25 | 0.5 | x | x | x |
| 35 | 0.2 | 0.75 | 0.25 | 1.0 | ∘ | ∘ | ∘ |
| 36 | 0.2 | 0.75 | 0.25 | 2.0 | ∘ | ∘ | ∘ |

TABLE 6

| | Compositional ratio (atomic ratio) | | | | | | |
|---|---|---|---|---|---|---|---|
| | of oxide semiconductor | | | Ti oxide film (TiOx) | Properties | | |
| No. | In(Zn + Sn + Ga) | Zn/(Zn + Sn) | Sn/(Zn + Sn) | Oxygen ratio (x) | Diffusion | Adhesion | Total evaluation |
| 1 | 0.05 | 0.5 | 0.5 | — | x | x | x |
| 2 | 0.05 | 0.5 | 0.5 | 0.5 | x | x | x |
| 3 | 0.05 | 0.5 | 0.5 | 1.0 | ∘ | ∘ | ∘ |
| 4 | 0.05 | 0.5 | 0.5 | 2.0 | ∘ | ∘ | ∘ |
| 5 | 0.05 | 0.67 | 0.33 | — | x | x | x |
| 6 | 0.05 | 0.67 | 0.33 | 0.5 | x | x | x |
| 7 | 0.05 | 0.67 | 0.33 | 1.0 | ∘ | ∘ | ∘ |
| 8 | 0.05 | 0.67 | 0.33 | 2.0 | ∘ | ∘ | ∘ |
| 9 | 0.05 | 0.75 | 0.25 | — | x | x | x |
| 10 | 0.05 | 0.75 | 0.25 | 0.5 | x | x | x |
| 11 | 0.05 | 0.75 | 0.25 | 1.0 | ∘ | ∘ | ∘ |
| 12 | 0.05 | 0.75 | 0.25 | 2.0 | ∘ | ∘ | ∘ |
| 13 | 0.1 | 0.5 | 0.5 | — | x | x | x |
| 14 | 0.1 | 0.5 | 0.5 | 0.5 | x | x | x |
| 15 | 0.1 | 0.5 | 0.5 | 1.0 | ∘ | ∘ | ∘ |
| 16 | 0.1 | 0.5 | 0.5 | 2.0 | ∘ | ∘ | ∘ |

TABLE 7

| | Compositional ratio (atomic ratio) | | | | | | |
|---|---|---|---|---|---|---|---|
| | of oxide semiconductor | | | Ti oxide film (TiOx) | Properties | | |
| No. | In/(Zn + Sn + Ga) | Zn/(Zn + Sn) | Sn/(Zn + Sn) | Oxygen ratio (x) | Diffusion | Adhesion | Total evaluation |
| 17 | 0.1 | 0.67 | 0.33 | — | x | x | x |
| 18 | 0.1 | 0.67 | 0.33 | 0.5 | x | x | x |
| 19 | 0.1 | 0.67 | 0.33 | 1.0 | ∘ | ∘ | ∘ |
| 20 | 0.1 | 0.67 | 0.33 | 2.0 | ∘ | ∘ | ∘ |
| 21 | 0.1 | 0.75 | 0.25 | — | x | x | x |
| 22 | 0.1 | 0.75 | 0.25 | 0.5 | x | x | x |
| 23 | 0.1 | 0.75 | 0.25 | 1.0 | ∘ | ∘ | ∘ |
| 24 | 0.1 | 0.75 | 0.25 | 2.0 | ∘ | ∘ | ∘ |
| 25 | 0.2 | 0.5 | 0.5 | — | x | x | x |
| 26 | 0.2 | 0.5 | 0.5 | 0.5 | x | x | x |
| 27 | 0.2 | 0.5 | 0.5 | 1.0 | ∘ | ∘ | ∘ |
| 28 | 0.2 | 0.5 | 0.5 | 2.0 | ∘ | ∘ | ∘ |
| 29 | 0.2 | 0.67 | 0.33 | — | x | x | x |
| 30 | 0.2 | 0.67 | 0.33 | 0.5 | x | x | x |
| 31 | 0.2 | 0.67 | 0.33 | 1.0 | ∘ | ∘ | ∘ |
| 32 | 0.2 | 0.67 | 0.33 | 2.0 | ∘ | ∘ | ∘ |

TABLE 8

| | Compositional ratio (atomic ratio) | | | | | | |
|---|---|---|---|---|---|---|---|
| | of oxide semiconductor | | | Ti oxide film (TiOx) | Properties | | |
| No. | In/(Zn + Sn + Ga) | Zn/(Zn + Sn) | Sn/(Zn + Sn) | Oxygen ratio (x) | Diffusion | Adhesion | Total evaluation |
| 33 | 0.2 | 0.75 | 0.25 | — | x | x | x |
| 34 | 0.2 | 0.75 | 0.25 | 0.5 | x | x | x |
| 35 | 0.2 | 0.75 | 0.25 | 1.0 | ∘ | ∘ | ∘ |
| 36 | 0.2 | 0.75 | 0.25 | 2.0 | ∘ | ∘ | ∘ |

Table 1 to Table 8 differ in the composition of the oxide semiconductors. Table 1 shows the results of the case where IGZO was used; Table 2 shows the results of the case where ZTO was used; Tables 3 to 5 each show the results of the case where GZTO was used; and Tables 6 to 8 each show the results of the case where IZTO was used. In Table 1, the ratio of In, Ga and Zn in the column of “compositional ratio of IGZO” means the compositional ratio (atomic % ratio) of In/Ga/Zn constituting IGZO.

In each Table, “Ti oxide film (TiOx)=-” (for example, No. 1 and the like in Table 1) means the case using a pure Ti film (thickness 50 nm) alone as the metal interconnection film but not using a Ti oxide film (TiOx), and the case corresponds to a conventional case.

From these Tables, when a Ti oxide film (TiOx) specifically defined in the present invention is used as the barrier layer in any case of using an oxide semiconductor having any composition, then the oxide semiconductor layer constituent elements can be prevented from diffusing into the Cu film and the adhesion between the barrier layer and the oxide semiconductor is good. Accordingly, no peeling of the metal film including the barrier layer (TiOx/pure Ti/pure Cu) was occurred. As opposed to these, in the case where a pure Ti film alone was used, the oxide semiconductor layer constituent elements could not be prevented from diffusing, and the adhesion was low.

Regarding the composition of the Ti oxide (TiOx) for use for the barrier layer, those in which the oxygen ratio (x) is outside the range defined in the present invention caused the same problems (diffusion of oxide semiconductor layer constituent elements and low adhesion) as those that occurred when a pure Ti film was used.

The above show the results of the case where a laminated film of pure Ti and pure Cu was used as the metal interconnection film; however, it has been confirmed through experiments that the other embodiments (laminated film of pure Ti and pure Al, laminated film of pure Ti and Cu alloy, laminated film of pure Ti and Al alloy, as well as single-layered film of pure Cu alone, pure Al alone, Cu alloy alone, or Al alloy alone) gave the same results as those in the above.

While the present invention has been described in detail and with reference to specific embodiments thereof, it will be apparent to one skilled in the art that various changes and modifications can be made therein without departing from the spirit and scope thereof.

This application is based on Japanese Patent Application No. 2010-222002 filed on Sep. 30, 2010 and Japanese Patent Application No. 2011-215071 filed on Sep. 29, 2011, the entire subject matters of which are incorporated herein by reference.

### INDUSTRIAL APPLICABILITY

According to the present invention, in the interconnection structure including an oxide semiconductor layer, a Ti oxide is used in place of Ti metal as the barrier layer for effectively preventing the metal constituting the interconnection material from diffusing into the oxide semiconductor; and therefore, stable TFT properties can be obtained, and a display device having a further enhanced quality can be provided.

### DESCRIPTION OF REFERENCE NUMERALS AND SIGNS

1 Substrate
2 Gate Electrode
3 Gate Insulating Film
4 Oxide Semiconductor Layer
5 Source/Drain Electrode
6 Protective Film (insulating film)
7 Contact Hole
8 Transparent Conductive Film
9 Ti Oxide Film

1. An interconnection structure, including a semiconductor layer of a thin-film transistor and a metal interconnection film above a substrate in this order from a side of the substrate, and including a barrier layer between the semiconductor layer and the metal interconnection film, wherein
the semiconductor layer is composed of an oxide semiconductor,
the barrier layer is composed of a Ti oxide film containing TiOx (where x is from 1.0 to 2.0), and the Ti oxide film is directly connected to the semiconductor layer, and
the oxide semiconductor is composed of an oxide containing at least one element selected from the group consisting of In, Ga, Zn and Sn.

2. The interconnection structure according to claim 1, wherein
the metal interconnection film has a single-layer structure or a laminated structure,
when the metal interconnection film has the single-layer structure, the metal interconnection film is composed of a pure Al film, an Al alloy film containing 90 atomic % or more of Al, a pure Cu film, or a Cu alloy film containing 90 atomic % or more of Cu, and
when the metal interconnection film has the laminated structure, the metal interconnection film is composed of, in this order from the side of the substrate: a pure Ti film or a Ti alloy film containing 50 atomic % or more of Ti, and a pure Al film or an Al alloy film containing 90 atomic % or more of Al; or a pure Ti film or a Ti alloy film containing 50 atomic % or more of Ti, and a pure Cu film or a Cu alloy film containing 90 atomic % or more of Cu.

3. A display device, including the interconnection structure according to claim 1.

4. A display device, including the interconnection structure according to claim 2.
